(19) United States
(12) Patent Application Publication
(10) Pub. No.: US 2023/0237241 A1
(43) Pub. Date: Jul. 27, 2023

(54) FINITE STATE MACHINE REPAIR CIRCUITRY

(71) Applicant: NORDIC SEMICONDUCTOR ASA, Trondheim (NO)

(72) Inventors: Joni JÄNTTI, Oulu (FI); Jaakko HAAPALAHTI, Oulu (FI)

(21) Appl. No.: 18/100,270

(22) Filed: Jan. 23, 2023

(30) Foreign Application Priority Data
Jan. 25, 2022 (FI) 20225056

(51) Int. Cl. G06F 30/398

(52) U.S. Cl. CPC G06F 30/398

(57) ABSTRACT

According to an aspect, there is provided a finite state machine repair circuitry comprising: at least one control unit, and at least one memory for storing instructions to be executed by the at least one control unit, wherein the at least one memory and the instructions are configured to, with the at least one control unit, cause the finite state machine repair circuitry at least to perform: causing overriding at least one of one or more input and/or output signals of a finite state machine circuit by corresponding one or more override signals generated by the finite state machine repair circuitry so as to a form a channel mimicking operation of said finite state machine circuit.

### TECHNICAL FIELD

Various example embodiments relate to finite state machines.

### BACKGROUND

S Finite state machines (FSMs), i.e., synchronous sequential circuits, are commonly used in various application for implementing digital control logic. FSMs have the benefit of being very efficient in terms of silicon area and power consumption. However, they possess a significant disadvantage in that their hard-coded functionality cannot be changed without silicon re-spin (i.e., without a design correction followed by re-fabrication) which is both expensive and time-consuming. State machines can contain programmability though implementation of a fully programmable state machine is expensive if there are many inputs and states.

### BRIEF DESCRIPTION

According to a first aspect, there is provided a finite state machine repair circuitry. The finite state machine repair circuitry comprises: at least one control unit, and at least one memory for storing instructions to be executed by the at least one control unit, wherein the at least one memory and the instructions are configured to, with the at least one control unit, cause the finite state machine repair circuitry at least to perform:

causing overriding at least one of one or more input signals and/or one or more output signals of a finite state machine circuit by corresponding one or more override signals generated by the finite state machine repair circuitry so as to a form a channel mimicking, fully or partly, correct operation of said finite state machine circuit.

According to a second aspect, there is provided a method comprising:

causing overriding at least one of one or more input signals and/or one or more output signals of a finite state machine circuit by corresponding one or more override signals so as to a form a channel mimicking, fully or partly, correct operation of said finite state machine circuit.

According to a third aspect, there is provided a computer readable medium comprising program instructions stored thereon for performing at least the following:

causing overriding at least one of one or more input signals and/or one or more output signals of a finite state machine circuit by corresponding one or more override signals so as to a form a channel mimicking, fully or partly, correct operation of said finite state machine circuit.

The first, second and third aspects provide the technical effect that a finite state machine circuit may be overridden fully or partly, for example, in the case of full or partial malfunctioning of the finite state machine circuit.

The first, second and third aspects provide the advantage that they do not require the use of a large lookup table (LUT) or a central processing unit (CPU). The first, second and third aspects may correspond to a midway point between hard-coded finite state machine circuits and a CPU in terms of area and power consumption. Compared to traditional LUT-based finite state machine circuits, the first, second and third aspects do not drive selected output signals but carry out register writes to bus system and hence is able to control vast number or features. Compared to traditional sequencer-based solutions, the first, second and third aspects take into account feedback (i.e., external signals) and alter the control sequence accordingly. The first, second and third aspects are also capable of emulating multiple finite state machine circuits simultaneously. Compared to the CPU-based solutions, the cost is also significantly reduced. Further, the first, second and third aspects may be implemented using an analog oriented silicon process.

Embodiments are defined in the dependent claims. The scope of protection sought for various embodiments is set out by the independent claims.

The embodiments and features, if any, described in this specification that do not fall under the scope of the independent claims are to be interpreted as examples useful for understanding various embodiments of the invention.

### BRIEF DESCRIPTION OF DRAWINGS

In the following, example embodiments will be described in greater detail with reference to the attached drawings, in which

FIG. 1 illustrates a system architecture according to embodiments;

FIGS. 2 and 3 illustrate processes according to embodiments executable by a finite state machine repair circuitry;

FIG. 4 illustrates an exemplary finite state machine repair circuitry according to embodiments;

FIG. 5 illustrates a control unit of a finite state machine repair circuitry according to embodiments; and

FIGS. 6A and 6B illustrate a system corresponding to an exemplary use case for the finite state machine repair circuitry and a code execution example for said system.

### DETAILED DESCRIPTION OF SOME EMBODIMENTS

The following embodiments are only presented as examples. Although the specification may refer to “an”, “one”, or “some” embodiment(s) and/or example(s) in several locations of the text, this does not necessarily mean that each reference is made to the same embodiment(s) or example(s), or that a particular feature only applies to a single embodiment and/or example. Single features of different embodiments and/or examples may also be combined to provide other embodiments and/or examples.

As used in this application, the term ‘circuitry’ may refer to one or more or all of the following: (a) hardware-only circuit implementations, such as implementations in only analog and/or digital circuitry, and (b) combinations of hardware circuits and software (and/or firmware), such as (as applicable): (i) a combination of analog and/or digital hardware circuit(s) with software/firmware and (ii) any portions of hardware processor(s) with software, including digital signal processor(s), sequencer(s), finite state machine(s), software, and memory(ies) that work together to cause an apparatus to perform various functions, and (c) hardware circuit(s) and processor(s), such as a microprocessor(s) or a portion of a microprocessor(s), that requires software (e.g. firmware) for operation, but the software may not be present when it is not needed for operation. This definition of ‘circuitry’ applies to all uses of this term in this application, including any claims. As a further example, as used in this application, the term ‘circuitry’ also covers an implementation of merely a hardware circuit or processor (or multiple processors) or a portion of a hardware circuit or processor and its (or their) accompanying software and/or firmware. The term ‘circuitry’ also covers, for example and if applicable to the particular claim element, a baseband integrated circuit for an access node or a terminal device or other computing or network device.

Finite state machines (FSMs), i.e., synchronous sequential circuits, are commonly used in various application for implementing digital control logic. According to a general definition, a finite state machine is any device (e.g., circuitry) capable of storing, at a given time, information on a state of plurality of available states (or specifically a finite number of available states) and of changing that state based on one or more received inputs, where the output of the finite state machine is dependent on the current state. Finite state machines may be equally called finite state machine circuits. Finite state machines have the benefit of being very efficient in terms of silicon area and power consumption. However, they possess a significant disadvantage in that their hard-coded functionality cannot be changed without silicon re-spin (i.e., without a design correction followed by re-fabrication) which is both expensive and time-consuming. State machines can contain programmability though implementation of a fully programmable state machine is expensive if there are many inputs and states.

Programmable finite state machine may be based, for example, on look-up tables (LUT) that define all combinations for current state and input signal states. This is a functional and practical way for implementing very small finite state machines (e.g., ones with 4 states, 4 inputs and 4 outputs). However, this type of implementation of a programmable finite state machine is impractical for large or mid-sized finite state machines as the size of the look-up table increases with the increasing number of states, inputs and outputs as all combinations need to covered.

For example for a finite state machine with 4 states, 4 inputs and 4 outputs, a lookup table of 2^{inputs}=16 cells is required for defining which state to enter next starting from a particular initial state. Each state corresponds to 2 bits. Moreover, every state requires 1 bit for each of the 4 outputs. For each state, 16*2+4=36 bits are needed. Thus, altogether 4*36=144 bits need to be reserved for the table in a memory. The size of this table in bits increases rapidly when the number of states/inputs/outputs is increased. Namely, the size of the table is 6208 bits for 8 states, 8 inputs and 8 outputs and 4194560 bits for 16 states, 16 inputs, 16 outputs.

Another way to implement programmable finite state machines is to run a programmable finite state machine using software (SW) on a (small) central processing unit (CPU). Implementing the CPU is not always possible or preferred. For example, many analog oriented silicon processes (power management, radio frequency (RF) frontend) fail to offer competitive memory modules. Further, CPU design may introduce additional costs due to royalty, debug ports or fast transistors. A CPU also always consumes more power than the equivalent finite state machine implemented in hardware as Reduced Instruction Set Computer (RISC) processor requires a fast clock.

Another alternative is to set up a sequencer to program functions in a flexible way. However, this type of solution does not correspond to a true finite state machine as two-way interaction with the controlled object is not enabled. Instead, such a sequencer is capable of executing only predefined sequences.

The embodiments to be discussed below seek to provide programmable, interaction capable finite state machine-based circuitry (a so-called FSM repair circuitry) which does not require a large LUT or CPU. The embodiments may correspond to a midway point between hard-coded finite state machines and CPU in terms of area and power consumption. Compared to traditional LUT-based finite state machines, the embodiments do not drive selected output signals but carry out register writes to bus system and hence is able to control vast number or features. Compared to traditional sequencer-based solutions, the embodiments take into account feedback (i.e., external signals or equally external feedback signal) and alter the control sequence accordingly. The embodiments are also capable of emulating multiple finite state machines simultaneously. Compared to the CPU-based solutions, the cost of the embodiments is significantly reduced. Further, the embodiments may be implemented using an analog oriented silicon process.

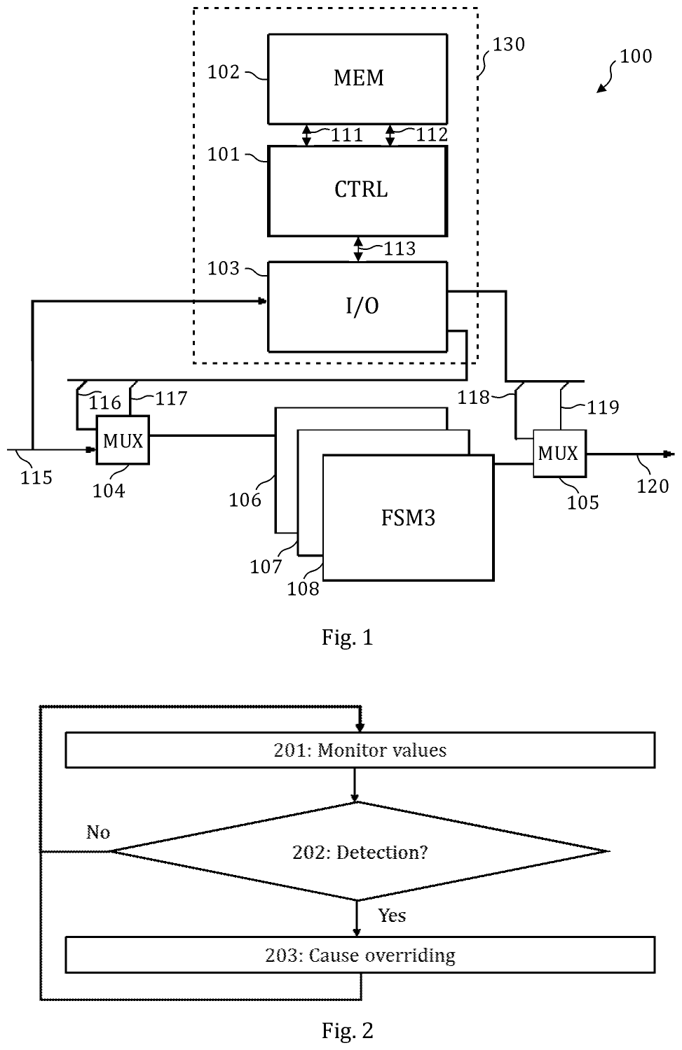

FIG. 1 illustrates a system 100 according to embodiments. The system 100 comprises a plurality of finite state machines 106 to 108 and FSM repair circuitry 130 electrically connected via first and second override multiplexers (MUXs) 104, 105 to said plurality of finite state machines 106 to 108 for overriding one or more them either fully or partly. In other embodiments, one or more finite state machines may be provided instead of the plurality of finite state machines (specifically, three finite state machines) shown in FIG. 1. The system 100 may correspond to a power management integrated circuit (PMIC) or a part thereof.

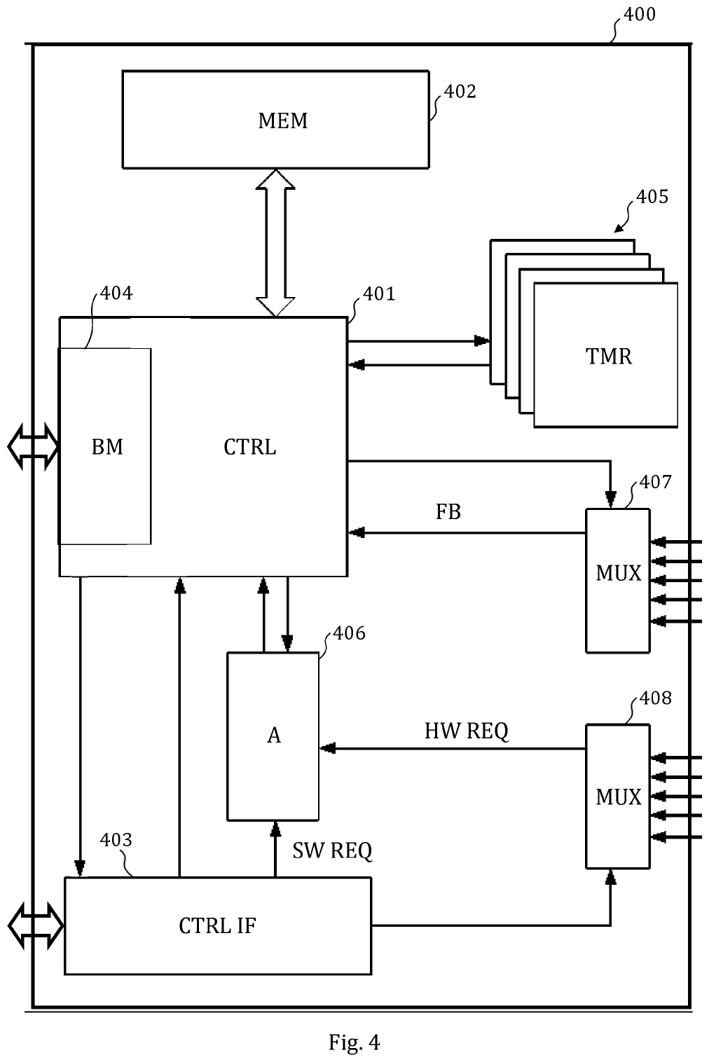

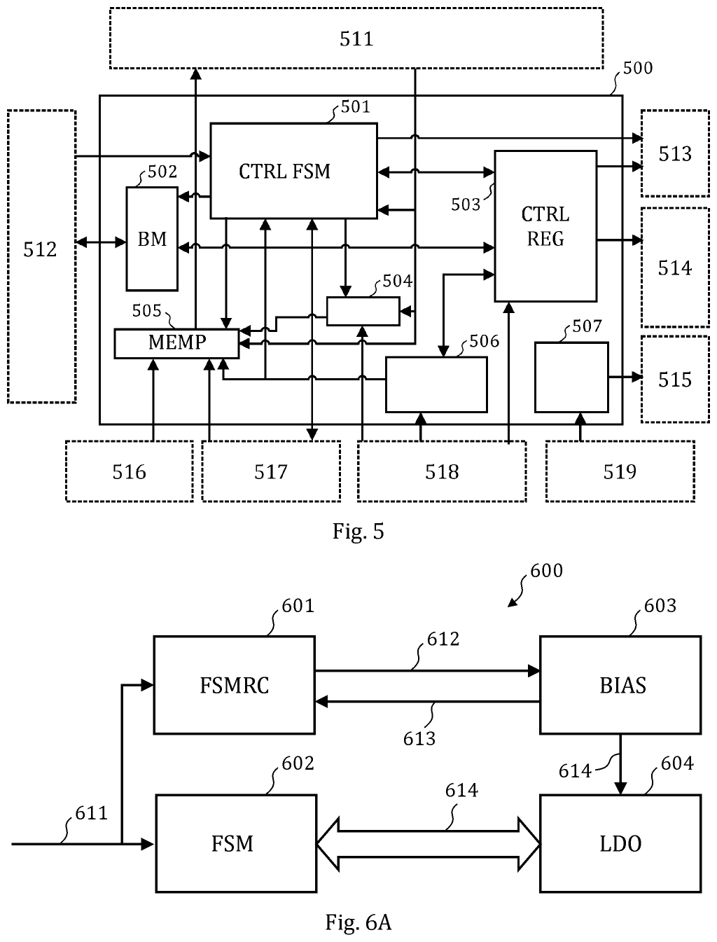

FIG. 1 depicts an example of simplified system architecture only showing some elements and functional entities, all being logical units, whose implementation may differ from what is shown. The connections shown in FIG. 1 are logical connections; the actual physical connections may (or may not) be different. It is apparent to a person skilled in the art that the system typically comprises also other functions and structures than those shown in FIG. 1. Examples of more detail implementations of certain parts of the system 100 are discussed in connection with FIGS. 4 and 5.

Referring to FIG. 1, the FSM repair circuitry 130 is circuitry which may be programmed or configured to patch any of the plurality of finite state machines 106 to 108 which have encountered problems or are limited in features. The plurality of finite state machines 106 to 108 or at least some of them may, in some embodiments, be specifically hard-coded (i.e., non-programmable) finite state machines. The FSM repair circuitry 130 comprises at least the following elements: a controller (CTRL) 101, at least one memory (MEM) 102 electrically connected to the controller 101 and one or more interfaces (or inputs/outputs, I/O) 103 for (electrically) connecting at least to the first and second override multiplexers 104, 105.

The controller 101 (equally called controller circuitry, a controller circuit, control circuitry, a control circuit or a control unit) of the FSM repair circuitry 130 may be configured to operate to some extent similar to a CPU or sequencer. Namely, the controller 101 is configured to read commands or instructions (as indicated by the arrow 112) from said at least one memory 102 and to process said commands in a similar manner to a simple CPU or sequencer. Moreover, the controller 101 may be configured to access full address space (similar to a CPU). The controller 101 may be a digital circuit.

The main difference between the controller 101 and a (typical) CPU or sequencer is that the controller 101 is configured to monitor external signals (or equally external feedback signals) associated with the plurality of finite state machines 106 to 108 (that is, signals normally input only to the plurality of finite state machines 106 to 108 for triggering their operation). When required, e.g., due to faulty operation of one of the plurality of finite state machines 106 to 108, the controller 101, with the at least one memory 102, may be configured to mimic, fully or partly, the operation of the finite state machine in question efficiently and accurately. This mimicking may be triggered by reception of one of said external feedback signals. In other words, the controller 101 is capable, with the at least one memory 102, of serving as a patch resource for any of the plurality of finite state machines 106 to 108 by establishing or activating at least one channel. At least one channel per finite state machine may be established by the FSM repair circuitry 130. Thus, any of the plurality of finite state machines 106 to 108 may, thus, be fixed without expensive and time-consuming silicon re-spin.

As hinted above, the FSM repair circuitry 130 may be configured to override a given finite state machine fully or partly. When a finite state machine is to be overridden fully, the controller 101 of the FSM repair circuitry 130 is configured to receive all input signals 115 of the finite state machine, read commands 112 (corresponding to normal operation of the overridden finite state machine) from said at least one memory 102 and to provide one or more override signals for replacing all output signal(s) of the finite state machine. When a finite state machine is to be overridden only partly, the controller 101 of the FSM repair circuitry 130 may be configured to receive one or more input signals 115 of the finite state machine (all or a part thereof), read commands 112 (corresponding to normal operation of the overridden finite state machine) from said at least one memory 102 and to provide one or more override signals for replacing some of the output signal(s) of the finite state machine. Alternatively, the controller 101 of the FSM repair circuitry 130 may be configured to receive one or more input signals 115 of the finite state machine (all or a part thereof), read commands 112 (corresponding to normal operation of the overridden finite state machine) from said at least one memory 102 and to provide one or more override signals for replacing some or all of the input signals of the finite state machine.

In some embodiments, the FSM repair circuitry 130 may also be configured to create a new finite state machine (i.e., a finite state machine not intended to replace any existing finite state machine), e.g., for setting a register bit set when a particular input pin changes its state.

The controller 101 of the FSM repair circuitry 130 is further configured to read (in addition to the commands) configuration information (as indicated by the arrow 111) from said at least one memory 102. Based on said configuration information, the controller 101 may, e.g., configure a channel start address to indicate a first command from said at least one memory 102 and/or configure channel to be triggered from correct external signal or start channel by software (SW) task.

The controller 101 of the FSM repair circuitry 130 may be configured to access its own control registers (not visible in FIG. 1). The controller 101 may not only be able to control register bits driven by any of the plurality of finite state machines 106 to 108 but also ones that are not originally driven by any of the plurality of finite state machines 106 to 108.

The operation of the controller 101 may be based on at least one finite state machine, i.e., the controller 101 may comprise (or even consist of) at least one finite state machine circuit. An exemplary implementation of the controller 101 is discussed below in connection with FIG. 5.

The at least one memory 102 may be implemented using any suitable data storage technology, such as semiconductor based memory devices, flash memory, magnetic memory devices and systems, optical memory devices and systems, fixed memory, removable memory, random access memory (RAM), one-time programmable memory (OTP) and register(s).

The interfaces 103 of the FSM repair circuitry 130 may comprise one or more input (communication) interfaces and/or one or more output (communication) interfaces. The interfaces 103 may involve one or more communication protocols.

The interfaces 103 may comprise at least interfaces for receiving input signals of the plurality of finite state machines 106 to 108 (as depicted with line 115) and controlling and providing value signals (equally called override signals) to the first and second override multiplexers 104, 105 (as depicted with lines 116 to 119). The input signals of the plurality of finite state machines 106 to 108 may comprise one or more external (feedback) signals for triggering operation of a finite state machine or equivalent operation by the FSM repair circuitry 130. The one or more external signals may be specifically external acknowledgment signals for acknowledging one or more actions (e.g., a transmission of a particular signal) carried out by the one or more finite state machines or other external status signals (associated, at least indirectly, with the operation of the one or more finite state machines).

The interfaces 103 may comprise one or more bus interfaces such as at least one bus master interface and at least one bus slave interface. The interfaces 103 may comprise, e.g., one or more register banks and/or one or more multiplexers.

While the interfaces 103 are depicted as a separate (but connected) element from the controller 101, in some embodiments, one or more of the interfaces 103 may form an intrinsic part of the controller 101.

Each of the plurality of finite state machines 106 to 108 may be configured to receive one or more input signals 115. Said one or more input signals 115 may be received also by the FSM repair circuitry 101, as described above. Said one or more input signals 115 may originate, for example, from an analog module, an input/output (JO) device, one or more other finite state machines and/or a control register. Further, each of the plurality of finite state machines 106 to 108 may be configured to transmit one or more output signals 120. Said one or more output signals 120 may be fed, for example, to an analog module, an IO device, one or more other finite state machines and/or a control register.

While FIG. 1 shows explicitly only a single first (or input) override multiplexer 104 and a single second (or output) override multiplexer 105, in practice, at least one first override multiplexer and/or at least one second override multiplexer per finite state machine 106 to 108 may be provided. Namely, a separate first override multiplexer 104 may be provided for each input of a finite state machine 106 to 108 and/or a separate second override multiplexer 105 may be provided for each output of a finite state machine 106 to 108. Each first override multiplexers 104 may be configured to output either an input signal 115 of one of the plurality of finite state machines 106 to 108 or a first override signal 116 received from the FSM repair circuitry 130 based on select line input 117 (also received from the FSM repair circuitry 130). Each second override multiplexer 105 may be configured to output either an output signal of one of the plurality of finite state machines 106 to 108 or a second override signal output signal 118 received from the FSM repair circuitry 130 based on a select line input 119 (also received from the FSM repair circuitry 130). The select line inputs 117, 119 determine whether or not the overriding is active at a given time.

In some alternative embodiments, the overriding of the inputs and outputs of the finite state machines 106 to 108 may be implemented, respectively, using first and second overriding means other than the first and second override multiplexers 104, 105. Such alternative first and second overriding means may comprise, for example, means for forcing an input signal of a given finite state machine to logical high (e.g., a logical AND gate) or logical low (e.g., a logical OR gate). In general, said first overriding means for overriding one or more inputs of one or more finite state machines may comprise one or more first override multiplexers and/or one or more first logical OR gates and/or one or more first logical AND gates. Similarly, said second overriding means for overriding one or more outputs of one or more finite state machines may comprise one or more second override multiplexers and/or one or more second logical OR gates and/or one or more second logical AND gates.

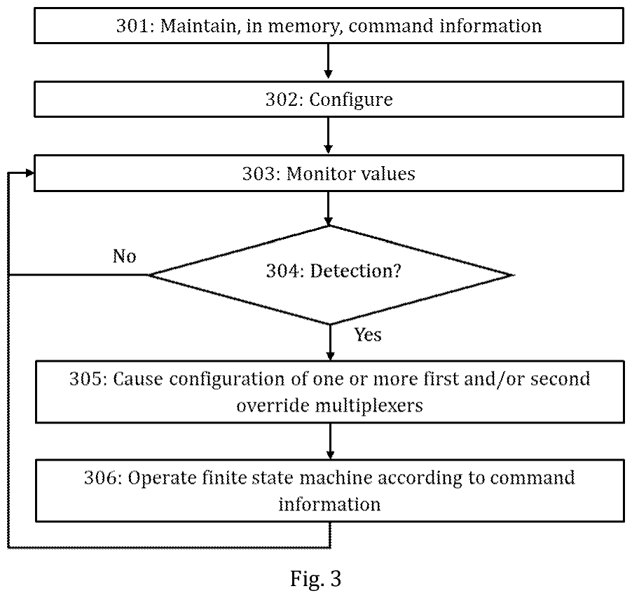

FIG. 2 illustrates a process according to embodiments for overriding a finite state machine by an FSM repair circuitry. The process may be carried out by the FSM repair circuitry such as the FSM repair circuitry 130 of FIG. 1 or its more detailed implementation to be discussed in connection with FIG. 4. Specifically, at least one control unit of the FSM repair circuitry and at least one memory of the FSM repair circuitry for storing instructions to be executed by the at least one control unit may be configured so as to cause the FSM repair circuitry to carry out the illustrated process.

Referring to FIG. 2, the FSM repair circuitry monitors, in block 201, values of one or more external signals. The one or more external signals may be signals for triggering operation of the one or more finite state machines, that is, signals normally input to the one or more finite state machines for triggering their operation. The one or more external signals may be or comprise one or more external acknowledgment signals. The one or more external acknowledgment signals may be signals transmitted by external devices or circuitry which are configured to receive one or more signals from the one or more finite state machines (either directly or via one or more other devices or circuitry). The value or form of the acknowledgment signal may be dependent on whether a signal was received success-fully from the finite state machine. For example, a positive acknowledgement (ACK) may be transmitted, by an external device or circuitry, if a signal expected for correct operation was received and a negative acknowledgement (NACK) may be transmitted, by an external device or circuitry, if no signal was received or a different signal than what is expected for correct operation was received.

The FSM repair circuitry determines, in block 202, whether or not a value for one of the one or more external signals satisfying one or more pre-defined criteria (e.g., defining a pre-defined value to be detected) is detected. The FSM repair circuitry may check each or at least some of the one or more external signals in block 202.

The one or more pre-defined criteria may be defined for each channel (i.e., for each finite state machine or for each external signal). Said one or more pre-defined criteria may comprise, for example, one or more pre-defined values, one or more pre-defined value ranges and/or one or more pre-defined upper and/or lower thresholds (for values). Said one or more pre-defined criteria may, in some embodiments, simply comprise check regarding whether a signal has the form of a negative acknowledgment.

In response to detecting a value the one or more pre-defined criteria in block 202, the FSM repair circuitry causes or triggers, in block 203, overriding at least one of one or more input signals and/or one or more output signals of said finite state machine (i.e., overriding one or more signals each of which is either an input signal of said finite state machine or an output signal of said finite state machine) by corresponding one or more override signals. Said one or more override signals may be generated by the finite state machine repair circuitry based on said one or more input signals of the finite state machine. Thus, a channel mimicking, fully or partly, the correct operation of said finite state machine is established or started. Said channel may fully or partly circumvent the finite state machine so as to compensate for the faulty operation of the finite state machine or to alter its operation. Said generating may be based on the one or more (original or pre-overriding) input signals of the finite state machine (i.e., the one or more input signals which would be fed to the finite state machine without the overriding as illustrated with element 115 of FIG. 1). Said one or more input signals may comprise said one or more external signals and/or one or more other signals. Said causing of the overriding of said at least one of one or more input signals and/or one or more output signals of said finite state machine may be carried out via first and second override multiplexers, as discussed above in connection with FIG. 1.

To give an example of partial overriding of a finite state machine, a particular finite state machine may be triggered to perform a first operation (e.g., shutdown) upon receiving one of first and second inputs from two respective circuits (e.g., a temperature detector and an overvoltage detector). If it is later desired to change the functioning of the circuit so that said first operation (e.g., shutdown) is triggered only by the first input while the second input is used for triggering a second operation (e.g., an interrupt), the FSM repair circuitry may be employed for overriding only the second input of the finite state machine and for implementing said second operation.

To enable the operation in blocks 201 to 202, configuration information may be maintained in said at least one memory of the FSM repair circuitry. The configuration information may define, for example, the one or more external signals to be monitored (i.e., which external signal to monitor for which channel) and/or one or more pre-defined criteria for the one or more finite state machines. The configuration information may define one or more channel start addresses (for one or more channels to be established) to indicate one or more respective first commands from said at least one memory.

In some embodiments, the one or more external signals may comprise a plurality of external (feedback) signals and, correspondingly, the one or more finite state machines may comprise a plurality of finite state machines, as implied in connection with FIG. 1. Thus, the FSM repair circuitry may be capable of establishing or activating a plurality of parallel channels for overriding the plurality of finite state machines (fully or at least partly). For example, the FSM repair circuitry may be configured to employ at least four channels for overriding at least four finite state machines. The smallest channel index may have the highest priority when multiple channels are active.

In some embodiments, the overriding in block 203 may be triggered, additionally or alternatively, in response to receiving a request (namely, a software and/or hardware request) by the FSM repair circuitry, as will be discussed in more detail below.

Some embodiments may comprise only block 203 of FIG. 2.

FIG. 3 illustrates another detailed process according to embodiments for overriding a finite state machine by an FSM repair circuitry. The process may be carried out by the FSM repair circuitry such as the FSM repair circuitry 130 of FIG. 1 or its more detailed implementation to be discussed in connection with FIG. 4. Specifically, at least one control unit of the FSM repair circuitry and at least one memory of the FSM repair circuitry for storing instructions to be executed by the at least one control unit may be configured so as to cause the FSM repair circuitry to carry out the illustrated process.

Referring to FIG. 3, it is initially assumed, in block 301, that command information for one or more channels for fully or partly overriding the one or more finite state machines is maintained in at least one memory of the FSM repair circuitry in block 301. The command information defines, for each channel, at least a set of one or more commands (i.e., a command sequence) for operating the channel so that (correct) operation of a corresponding finite state machine is replicated, fully or partly, by the finite state machine repair circuitry. Configuration information may also be maintained in said at least one memory, as described in connection with FIG. 2.

The FSM repair circuitry configures, in block 302, one or more channels to be triggered from one or more respective external signals satisfying one or more respective pre-defined criteria. Additionally, the FSM repair circuitry may configure, in block 302, triggering of the one or more channels (or a part thereof) by receiving one or more respective software requests. Actions pertaining to blocks 303, 304 may correspond, respectively, to actions described in connection with blocks 201, 202 of FIG. 2 above and are thus not repeated here for brevity.

In response to detecting a value for one of the one or more external signals satisfying one or more pre-defined criteria (e.g., matching a particular pre-defined value) in block 304, the FSM repair circuitry causes or triggers, in block 305, configuration of one or more first override multiplexers and/or one or more second override multiplexers to output one or more override signals received from (or generated by) the FSM repair circuitry. In other words, the FSM repair circuitry causes adjustment of the select lines (or select line signals) of the one or more first and/or second override multiplexers so that signal(s) outputted by the FSM repair circuitry are selected (instead of the normal input/output signal(s) of the finite state machine). Thus, as discussed also in connection with FIG. 2, a channel circumventing the finite state machine (at least partially) is established (or activated). Alternatively (if only at least one input signal is overridden), a channel for pre-processing at least one input signal of the finite state machine so as to compensate for the faulty operation of the finite state machine is established or started.

As described above, in some alternative embodiments, first and/or second overriding means other than said one or more first override multiplexers and/or said one or more second override multiplexers (e.g., AND and/or OR gates) may be used. Thus, the FSM repair circuitry may, in general, cause or trigger, in block 305, configuration of first overriding means and/or second overriding means to output one or more override signals received from (or generated by) the FSM repair circuitry.

Thereafter, the FSM repair circuitry operates, in block 306, the channel according to the command information maintained in said at least one memory (i.e., according to a command sequence defined by the command information) and optionally based on one or more inputs signals of the finite state machine. For example, the FSM repair circuitry may receive one or more input signals of the finite state machine and execute commands associated with said finite state machine from said at least one memory based on the one or more input signals. It should be noted that the FSM repair circuitry may be configured to receive the input signals of the one or more finite state machines even before the triggering of the channel, as shown in FIG. 1. The executing of the commands may comprise at least causing transmitting of at least one override signal via a first and/or second override multiplexer (by, e.g., writing to a particular register of a register bank of the FSM repair circuitry). Additionally or alternatively, the executing of the commands may comprise writing a register bit that was not previously controlled by any finite state machine.

In some embodiments, the FSM repair circuitry may execute commands associated with said finite state machine from said at least one memory without receiving any input signals of the finite state machine (or receiving the one or more input signals of the finite state machine but not utilizing them for operating the channel).

In some embodiments, each of the one or more channels (as defined in the command and/or configuration information) may be associated with a different start address in said at least one memory from which reading of the command information starts when the channel is operated (in block 305). The start address may be defined via a control interface (e.g., a register bank) of the FSM repair circuitry. The reading of the configuration information may end when a pre-defined end command is reached during the operation of the channel. When the operation of the channel is completed, the FSM repair circuitry resumes waiting for next triggering event for that channel.

In some embodiments, one or more of the following commands may be defined in the command information and may be executable by the FSM repair circuitry:

LASTWRITE: Writes data from at least one memory to a register address and channel executing ends (thus causing outputting an override signal or other register bit). May serve as a channel ending command.

WRITE: Write data from at least one memory to a register address.

DELAY: Delays channel execution (i.e., starts pause mode). In pause mode, other channels may still be allowed to be executed.

WAIT: Wait until external acknowledgement activates or timer ends. Hop (or jump) to branch address if the acknowledgement activated. In pause mode allow other channels to be executed.

CONFIG: Configures an external acknowledgement for a channel (i.e., an external signal to be monitored for a channel). This command may be executed in block 302.

CHECK: Check a value of an external acknowledge signal and hop to a branch address if the value matches a pre-defined value. This command may be executed in blocks 201, 201 of FIG. 2 or blocks 303, 304 of FIG. 3.

NACMD: Not used command. Stops channel and causes an error flag. It should be noted that names given to the commands described above are merely exemplary and other names may be equally used. In some embodiments, at least the WRITE, CHECK and LASTWRITE (and possibly CONFIG) commands (or equivalent commands) may be defined.

In some alternative embodiments, the FSM repair circuitry may cause the configuration of the first and second override multiplexers (and/or other first and second overriding means) as described in connection with block 305 at boot up of the FSM repair circuitry for all of the one or more channels. In other words, the configuration of the first and/or second overriding means may be carried out before the configuration in block 302 or at least before the monitoring in block 303. A separate channel may be reserved for said configuration.

Optionally, the FSM repair circuitry may cause disabling of at least one of the one or more finite state machines (or preventing booting up of at least one the one or more finite state machines) as a first step of the process of FIG. 3 (i.e., even before any other configuration is carried out) to prevent any possible damage which may be caused by operation of a faulty finite state machine. Namely, said at least one the one or more finite state machines may be disabled at least until the configuration of the first and second overriding means is carried out to completion.

It should be noted that the command information for the channel maintained in the at least one memory (or the one or more command sequences defined by the command information) may comprise also one or more commands not associated (directly) with overriding of the finite state machine. For example, the FSM repair circuitry may, according to the command sequence, take over a first signal of the finite state machine, drive it to (logical) high, wait for a pre-defined amount of time (e.g., 100 cycles), check a value of a second signal and if said value is at (logical) high, set the first signal to (logical) low. Obviously, the low/high values may be also interchanged in said example.

FIG. 4 illustrates an FSM repair circuitry 400 according to embodiments. The FSM repair circuitry 400 may correspond to a more detailed view of the FSM repair circuitry 130 of FIG. 1. Thus, any of the discussion provided in connection with FIG. 1 and/or FIGS. 2 and 3 may apply, mutatis mutandis, for the FSM repair circuitry 400 of FIG. 4.

The FSM repair circuitry 400 comprises a controller 401 and at least one memory 402 connected to the controller 401. These elements 401, 402 may correspond to elements 101, 102 of FIG. 1.

The controller 401 comprises (or is connected to) a bus master (BM) interface 404. The bus master interface 401 may be comprised in the interface element 103 of FIG. 1. According to a general definition, a bus master is a program that directs traffic on the computer bus or input/output paths. The bus master is the “master” and the I/O devices on the bus are the “slaves”. Here, the control interface (CTRL IF) 403 and/or the at least one memory 402 may provide bus slave interfaces (i.e., register banks). The bus master effectively controls the bus paths on which the address and control signals flow. Once these bus paths are set up, the flow of data bits goes directly between the I/O device and the controller 401. The bus master interface 404 may be employed here specifically for outputting or writing commands to external register banks, where at least some of these external register banks may be configured to control the select lines and some of the input lines of first and second override multiplexers for enabling the overriding. The sup-ported function may be a write transaction with wait states.

The FSM repair circuitry 400 further comprises at least one control interface 403. The control interface 403 may be comprised in the interface element 103 of FIG. 1. The at least one control interface 403 may correspond to a bus slave interface. The at least one control interface 403 may comprise at least one register bank (comprising control and/or status registers). The control interface 403 may be configured at least to provide start addresses of the channels to the controller 401 as well as providing software request to an arbiter (A) 406.

In addition to the at least one control interface 403 and bus master register 404, the FSM repair circuitry 400 is further configured to receive or read inputs via a first multiplexer 407 and a second multiplexer 408. The first multiplexer 407 may be configured to receive external (acknowledgement) signals (or feedback, FB) for monitoring (as described, e.g., in connection with block 201 of FIG. 2) and to output at least one of said one or more external signals to the controller 401. The first multiplexer 407 may be controllable by the controller 401 (i.e., the controller may be configured to control a select line of the first multiplexer 407).

In some embodiments, the first multiplexer 407 may be connected to the controller 401 directly and/or via a level selection unit (not shown in FIG. 4) for selecting, per channel, the level of the received external (acknowledgement) signal (e.g., between high and low logic levels corresponding to positive and negative acknowledgment signals). Said level selection unit may be used, for example, by the WAIT command mentioned above. The controller 401 may also be configured to control enabling/disabling of the level selection unit. In general, the level selection unit may be considered optional.

The second multiplexer 408 may be configured to receive hardware requests (HW REQs) for starting a channel (i.e., for overriding one of the plurality of finite state machines) and to output at least one of said one or more hardware requests to an arbiter 406. The second multiplexer 408 may be controllable via the control interface 403 (i.e., the control interface 403 may be configured to control a select line of the second multiplexer 408).

In summary, the FSM repair circuitry 400 (or specifically the controller 401) is configured to start or trigger a given channel either 1) in response to receiving a software request via the control interface 403 and the arbiter 406, 2) in response to receiving a hardware request (HW REQ) via the second multiplexer 408 and the arbiter 406 or 3) in response to an external (acknowledgment) signal received via the first multiplexer 407 having a value satisfying one or more pre-defined criteria (as described above, e.g., in connection with FIG. 2 or 3). In some embodiments, one or both of options 2) and 3) may be omitted.

As mentioned above, the FSM repair circuitry 400 further comprises an arbiter 406 (equally called an arbiter unit). The controller 401 is configured to perform arbitration (i.e., allocation of access to shared resources) using said arbiter 406. In other words, the arbiter 406 is used for enabling handling of situations where multiple channels are requested at the same time. To this end, the arbiter 406 is connected to the at least one control interface 403 for receiving software requests and to a second multiplexer 408 for receiving hardware requests. Thus, arbitration is carried out between software and hardware requests.

The principle implemented by the arbiter 406 may be that the lowest channel index is given the highest priority. The arbiter 406 may keep track which channel(s) are active and which channel(s) are pending or paused. The arbiter 406 may be configured to control pause mode of channels when a timer is set to calculate delay. In those cases, the channel is set into pause mode or state to release the controller 401 (or a finite state machine therein) to execute other channels in the meanwhile. The paused channel may be given a higher priority than the pending channel(s).

The arbiter 406 may specifically comprise a finite state machine for controlling the executing order of the channels. The arbiter 406 may further comprise one or more internal registers for keeping status of channel arbitration.

The controller 400 further comprises one or more timers 405 (TMRs) for enabling timing functionalities (e.g., calculating delays) of one or more channels associated with the one or more finite state machines, respectively. A given timer 405 may be started upon receiving a start timer request from the controller 401. The started timer 405 may run until a certain delay time value is reached. Each timer may be stopped and cleared by a clear timer request. The delay may be calculated in clock cycles of a clock signal. The WAIT command mentioned above is an example of a command execution of which requires the use of a timer 405.

FIG. 5 illustrates an exemplary controller (or a control unit or circuit) 500 of an FSM repair circuitry according to embodiments in detail. The controller 500 may correspond to a more detailed view of the controller 101 of FIG. 1 and/or the controller 401 of FIG. 4. Thus, any of the discussion provided in connection with FIGS. 1 to 4 may apply, mutatis mutandis, for the controller 500 of FIG. 5.

FIG. 5 depicts an example of a controller 500 showing elements and functional entities, all being logical units, whose implementation may differ from what is shown. The connections shown in FIG. 5 are logical connections; the actual physical connections may (or may not) be different.

The elements 511 to 519 of FIG. 5 indicating input/output connections are defined as follows:

511: to/from at least one memory,

512: to/from bus,

513: to timer,

514: to level select/MUX1,

515: to timer,

516: from control interface,

517: from/to arbiter,

518: from MUX1/level select and

519: from arbiter.

The controller 500 comprises a control finite state machine (CTRL FSM) 501, a bus master (BM) register 502, control registers (CTRL REG) 503, a check register 504, a memory pointer register (MEMP) 505, a continue register 506 and a clear timer register 507.

The control finite state machine 501 (i.e., a control synchronous sequential circuit) is configured to initiate and keep track of the channel execution (i.e., execution of one or more channels in parallel for overriding one or more finite state machines) and to send flag signals to internal subregisters depending on executed command(s). After a start channel request, the principle is to read a command from at least one memory of the FSM repair circuitry and carry out one or more action according to the command. This operation is repeated until a specific end command is read (e.g., LASTWRITE command as described above).

In some embodiments, a special pause mode may be implemented. In pause mode, the current channel execution stops and the control finite state machine goes back to off state until a specific resume channel request is received or another channel is requested to start by a start channel request.

The bus master interface 502 may be defined as described in connection with element 404 of FIG. 4. In summary, the bus master interface 502 is configured to handle bus writes to external registers.

The control registers 503 are supporting elements for the control finite state machine 501 which controls registering of signal values by raising up flags. Separate registers may be provided for each channel. However, only active channel registers may be accessible during the execution of channel(s).

The check register 504 is configured to implement (with the control finite state machine 501 and the memory pointer register 505) the CHECK command as described above. The check register 504 is configured to check, in response to a command from the control finite state machine 501, a value of an external acknowledge signal and cause hopping to a branch address using the memory pointer register 505 if the value matches a pre-defined value.

The memory pointer register 505 is configured to set the address for reading data from the at least one memory. It is also configured to handle address selecting, e.g., when starting, resuming and/or continuing a channel or when a value of a monitored external signal is checked.

The continue register 506 is, as the name implies, configured to cause continuing execution of a channel after a wait period.

The clear time register 507 is, as the name implies, configured to cause clearing of at least one of the one or more timers of the FSM repair circuitry. The timer may be cleared upon receiving a resume channel request for a channel (i.e., when an execution of a channel is resumed following a completion of a DELAY command). As described above, each of the one or more timers of the FSM repair circuitry may be associated with a particular one of the one or more channels which may be activated by the FSM repair circuitry.

In some embodiments, one or both of the elements 506, 507 may be omitted. In such embodiments, delaying and/or pausing execution of a channel may not be enabled.

It should be emphasized that FIG. 5 illustrates merely one exemplary implementation of a controller 500 which may be used in connection with embodiments (e.g., as the controller 101 of FIG. 1 and/or the controller 401 of FIG. 4). In other implementations, the controller may be implemented, for example, simply as a single finite state machine.

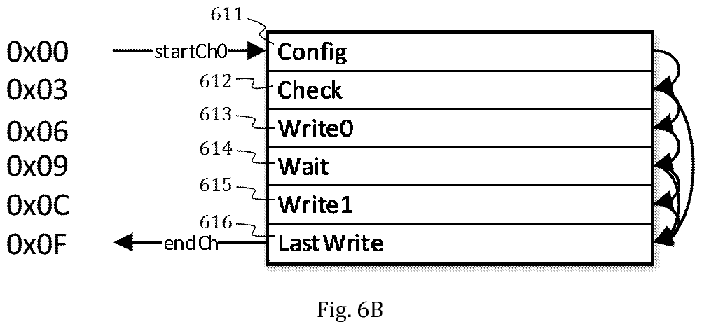

FIG. 6A illustrates a system 600 for illustrating one exemplary use case for the FSM repair circuitry according to embodiments. The FSM repair circuitry (FSMRC) 601 of FIG. 6A may correspond to FSM repair circuitry as described in connection with any of the embodiments above.

The system 600 of FIG. 6 comprises the FSM repair circuitry 601, a finite state machine which is overridable (i.e., repairable) by the FSM repair circuitry 601, a low-drop regulator (LDO) 604 and a biasing device 603 (e.g., a tunable voltage source or a device comprising a tunable voltage source) for supplying a bias voltage for the LDO 604.

It is assumed here that the LDO 604 requires a refreshed bias voltage 614 during start. This is achieved under normal circumstances by the FSM 602 requesting the biasing from the device 603. However, in the following example, it is assumed that no such biasing signals is received due to malfunctioning of the FSM 602 and thus no biasing voltage is provided for the LDO 604. To rectify this situation, the FSM repair circuitry checks whether or not the bias is refreshed, if it is not then requests refreshing of the bias via a force register (causing transmission of signal 613).

FSM repair circuitry 601 is configured to receive the same start LDO signal 611 which is received also by the FSM 602. This signal 611 serves as a starting point for the execution of the channel for overriding the FSM 602.

FIG. 6B illustrates an exemplary code execution example with branching for the system and use case of FIG. 6A. The illustrated exemplary code is executed by the FSM repair circuitry 601.

CONFIG (block 611): Configure a bias status signal 613 to acknowledge to the FSM repair circuitry.

CHECK (block 612): Check the bias status based on the bias status signal 613 and branch to LASTWRITE, if the bias status indicates that the bias was refreshed, if not then go next command WRITE0 to start requesting of refreshing.

WRITE0 (block 613): Write force register (logical) high (i.e., raise a flag by sending a flag signal to a particular internal subregister) to request (or force) bias refreshing (signal 612).

WAIT (block 614): Wait until bias is refreshed and go to LASTWRITE; if wait timeouts, go to next command WRITE1 to report an error.

WRITE1 (block 615): Write error flag (logical) high (i.e., raise an error flag by sending an error flag signal to a particular internal subregister).

LASTWRITE (block 616): Release bias refresh request force (i.e., lower the associated flag).

The blocks, related functions, and information exchanges described above by means of FIGS. 2, 3 and 6B are in no absolute chronological order, and some of them may be performed simultaneously or in an order differing from the given one. Other functions can also be executed between them or within them, and other information may be sent and/or received, and/or other mapping rules applied. Some of the blocks or part of the blocks or one or more pieces of information can also be left out or replaced by a corresponding block or part of the block or one or more pieces of information.

The techniques and methods described herein may be implemented by various means. For example, these techniques may be implemented in hardware (one or more devices), firmware (one or more devices), software (one or more modules), or combinations thereof. For a hardware implementation, the apparatus(es) of embodiments may be implemented within one or more application-specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described herein, or a combination thereof. For firmware or software, the implementation can be carried out through modules of at least one chipset (procedures, functions, and so on) that perform the functions described herein. The software codes may be stored in a memory unit and executed by processors. The memory unit may be implemented within the processor or externally to the processor. In the latter case, it can be communicatively coupled to the processor via various means, as is known in the art. Additionally, the components of the systems described herein may be rearranged and/or complemented by additional components in order to facilitate the achievements of the various aspects, etc., described with regard thereto, and they are not limited to the precise configurations set forth in the given figures, as will be appreciated by one skilled in the art.

Embodiments as described may also be carried out in the form of a computer process defined by a computer program or portions thereof. Embodiments of the methods described in connection with at least FIGS. 2, 3 and 6B may be carried out, fully or at least in part, by executing at least one portion of a computer program comprising corresponding instructions. The computer program may be provided as a computer readable medium comprising program instructions stored thereon or as a non-transitory computer readable medium comprising program instructions stored thereon. The computer program may be in source code form, object code form, or in some intermediate form, and it may be stored in some sort of carrier, which may be any entity or device capable of carrying the program. For example, the computer program may be stored on a computer program distribution medium readable by a computer or a processor or other control unit. The computer program medium may be, for example but not limited to, a record medium, computer memory, read-only memory, electrical carrier signal, telecommunications signal, and software distribution package, for example. The computer program medium may be a non-transitory medium. Coding of software for carrying out the embodiments as shown and described is well within the scope of a person of ordinary skill in the art.

Embodiments described herein are applicable to systems defined above but also to other systems. The specifications of the systems and their elements develop rapidly. Such development may require extra changes to the described embodiments. Therefore, all words and expressions should be interpreted broadly and they are intended to illustrate, not to restrict, the embodiment. It will be obvious to a person skilled in the art that, as technology advances, the inventive concept can be implemented in various ways. Embodiments are not limited to the examples described above but may vary within the scope of the claims.

1. A finite state machine repair circuitry comprising:
at least one control unit, and
at least one memory for storing instructions to be executed by the at least one control unit, wherein the at least one memory and the instructions are configured to, with the at least one control unit, cause the finite state machine repair circuitry at least to perform:
causing overriding at least one of one or more input signals and/or one or more output signals of a finite state machine circuit by corresponding one or more override signals generated by the finite state machine repair circuitry so as to a form a channel mimicking, fully or partly, correct operation of said finite state machine circuit.

2. The finite state machine repair circuitry according to claim 1, wherein the at least one memory and the instructions are configured to, with the at least one control unit, cause the finite state machine repair circuitry to operate the channel based on the one or more input signals of the finite state machine circuit.

3. The finite state machine repair circuitry according to claim 1, wherein the at least one memory and the instructions are configured to, with the at least one control unit, cause the finite state machine repair circuitry to perform:
maintaining, in said at least one memory, command information for one or more channels for fully or partly overriding one or more finite state machine circuits, wherein the command information defines, for each channel, at least a set of one or more commands for operating the channel so that correct operation of a corresponding finite state machine circuit is replicable by the finite state machine repair circuitry; and
operating the channel according to the command information.

4. The finite state machine repair circuitry according to claim 3, further comprising:
a control interface,
wherein the at least one memory and the instructions are configured to, with the at least one control unit, cause the finite state machine repair circuitry to start the operating of the channel according to the command information maintained in said at least one memory from a start address of said at least one memory defined, before the operating of the channel, via the control interface and to end the operating of the channel according to the command information when a pre-defined end command is read.

5. The finite state machine repair circuitry according to claim 4, wherein the at least one memory and the instructions are configured to, with the at least one control unit, cause the finite state machine repair circuitry to perform the overriding of said finite state machine circuit also in response to receiving a software request for activating the channel via the control interface and/or in response to receiving a hardware request for activating the channel.

6. The finite state machine repair circuitry according to claim 1, wherein said at least one of the one or more input signals and/or the one or more output signals comprises all or at least one of the one or more output signals of the finite state machine circuit.

7. The finite state machine repair circuitry according to claim 1, wherein the at least one memory and the instructions are configured to, with the at least one control unit, cause the finite state machine repair circuitry to perform the causing of the overriding separately for a plurality of finite state machine circuits, the plurality of finite state machine circuits comprising the finite state machine circuit.

8. The finite state machine repair circuitry according to claim 1, wherein the at least one memory and the instructions are configured to, with the at least one control unit, cause the finite state machine repair circuitry to perform:
monitoring values of one or more external feedback signals for triggering operation of one or more finite state machine circuits comprising the finite state machine circuit; and
performing the causing of the overriding in response to detecting a value for one of the one or more external feedback signals satisfying one or more pre-defined criteria.

9. The finite state machine repair circuitry according to claim 8, wherein the one or more pre-defined criteria comprise one or more pre-defined values.

10. The finite state machine repair circuitry according to claim 8,
wherein the one or more external feedback signals comprise a plurality of external feedback signals and the one or more finite state machine circuits comprise a plurality of finite state machine circuits, the one or more pre-defined criteria being defined separately for the plurality of external feedback signals.

11. The finite state machine repair circuitry according to claim 1, wherein the at least one memory and the instructions are configured to, with the at least one control unit, cause the finite state machine repair circuitry to cause the overriding by at least
causing configuration of first overriding means preceding the finite state machine circuit to output at least one first override signal receivable from the finite state machine repair circuitry to the finite state machine circuit, wherein the first overriding means comprise one or more first override multiplexers and/or one or more first logical OR gates and/or one or more first logical AND gates; and/or
causing configuration of second overriding means following the finite state machine circuit to output at least one second override signal receivable from the finite state machine repair circuitry, wherein the second overriding means comprise one or more second override multiplexers and/or one or more second logical OR gates and/or one or more second logical AND gates.

12. The finite state machine repair circuitry according to claim 7, further comprising:
an arbiter for performing arbitration for two or more channels requested, via software and/or hardware requests, for activating two or more channels for overriding, fully or partly, two or more of the plurality of finite state machine circuits, wherein the at least one memory and the instructions are configured to, with the at least one control unit, cause the finite state machine repair circuitry to cause the overriding also in response to receiving a software or hardware request for activating the channel; and
a second multiplexer configured to receive hardware requests for activating channels and to output at least one of said hardware requests to the arbiter.

13. The finite state machine repair circuitry according to claim 7, further comprising:
a control interface configured to receive software requests for activating channels and to output at least one of the software requests;
a second multiplexer configured to receive hardware requests for activating channels and to output at least one of said hardware requests; and
an arbiter for performing arbitration for two or more channels requested via software and hardware requests received via the control interface and the second multiplexer,
wherein the at least one memory and the instructions are configured to, with the at least one control unit, cause the finite state machine repair circuitry to perform:
monitoring values of a plurality of external feedback signals for triggering operation of the plurality of finite state machine circuits; and
in response to either detecting a value for one of the plurality of external feedback signals satisfying one or more pre-defined criteria or receiving a software request for channel activation via the control interface and the arbiter or a hardware request for channel activation via the second multiplexer and the arbiter, performing the causing of the overriding for a finite state machine circuit of the plurality of finite state machine circuits.

14. The finite state machine repair circuitry according to claim 1, further comprising:
a timer for implementing timing functionalities of the channel for, fully or partly, overriding the finite state machine circuit.

15. The finite state machine repair circuitry according to claim 7, further comprising:
a plurality of timers for implementing timing functionalities of a plurality of channels for, fully or partly, overriding the plurality of finite state machine circuits.

16. The finite state machine repair circuitry according to claim 8, further comprising:
a first multiplexer configured to receive the one or more external feedback signals and to output at least one of the one or more external feedback signals to the at least one control unit.

17. The finite state machine repair circuitry according to claim 13, further comprising:
a first multiplexer configured to receive the plurality of external feedback signals and to output at least one of the plurality of external feedback signals to the at least one control unit.

18. A system comprising:
a finite state machine repair circuitry comprising:
at least one control unit, and
at least one memory for storing instructions to be executed by the at least one control unit, wherein the at least one memory and the instructions are configured to, with the at least one control unit, cause the finite state machine repair circuitry at least to perform: causing overriding at least one of one or more input signals and/or one or more output signals of a finite state machine circuit by corresponding one or more override signals generated by the finite state machine repair circuitry so as to a form a channel mimicking, fully or partly, correct operation of said finite state machine circuit;
first overriding means for overriding one or more inputs of one or more finite state machine circuits with one or more first override signals received from the finite state machine repair circuitry, wherein the first overriding means comprise one or more first override multiplexers and/or one or more first logical OR gates and/or one or more first logical AND gates; and
second overriding means for overriding one or more outputs of the one or more finite state machine circuits with one or more second override signals received from the finite state machine repair circuitry, wherein the second overriding means comprise one or more second override multiplexers and/or one or more second logical OR gates and/or one or more second logical AND gates.

19. A method comprising:
causing overriding at least one of one or more input signals and/or one or more output signals of a finite state machine circuit by corresponding one or more override signals so as to a form a channel mimicking, fully or partly, correct operation of said finite state machine circuit.

20. A non-transitory computer readable medium comprising program instructions stored thereon for performing at least the following:
causing overriding at least one of one or more input signals and/or one or more output signals of a finite state machine circuit by corresponding one or more override signals so as to a form a channel mimicking, fully or partly, correct operation of said finite state machine circuit.
